(19) United States
(12) Patent Application Publication
(10) Pub. No.: US 2026/0322327 A1
(43) Pub. Date: Oct. 15, 2026

(54) DEMODULATION CIRCUIT, ISOLATION CIRCUIT, AND METHODS

(71) Applicant: Infineon Technologies Austria AG, Villach (AT)

(72) Inventors: Marco PARENZAN RUPENA, Villach (AT); Karl Egil NORLING, Villach (AT); Lucrezia NAVARIN, Vigonovo (IT); Andrea BEVILACQUA, Padova (IT); Andrea NEVIANI, Padova (IT)

(21) Appl. No.: 19/629,430

(22) Filed: Mar. 26, 2026

(30) Foreign Application Priority Data
Apr. 15, 2025 (DE) 102025114587.3

(51) Int. Cl. H03D 3/00; H03D 1/00

(52) U.S. Cl. CPC H03D 3/001; H03D 1/00

(57) ABSTRACT

A circuit for demodulating the FSK signal includes an input node configured to receive an FSK modulated signal, and a phase-voltage converter (PVC) unit including a first PVC input node connected to the input node, a second PVC input node, and a PVC output node. The PVC unit is configured to provide a control signal to the PVC output node based on a phase difference between the FSK modulated signal and a signal on the second PVC input node. A voltage controlled delay line (VCDL) unit includes a first VCDL input node connected to the input node, a second VCDL input node connected to the PVC output node, and a VCDL output node connected to the second PVC input. The VCDL unit is configured to adjust a phase of the FSK modulated signal based on the control signal, and provide the adjusted signal to the VCDL output node.

### CROSS-REFERENCE TO RELATED APPLICATION

This application claims priority to Germany Patent Application No. 102025114587.3, filed Apr. 14, 2025, the contents of which are incorporated herein by reference in their entireties.

### TECHNICAL FIELD

The present disclosure relates to circuits and methods for demodulating a frequency shift keying (FSK) modulated signal. The present disclosure further relates to an isolation circuit comprising an isolation barrier, and methods for communicating data across the isolation barrier.

### BACKGROUND

Various technologies require signaling schemes to enable communication over isolation barriers. One example are gate drives that isolate an output side from an input side. Most gate drivers include a communication channel communicatively coupling an input chip, which receives the control signal (PWM) from a controller and conditions the signal to be transmitted, to the output chip that drives a switch. The communication channel typically requires asynchronous data exchange, short propagation delay, and accurate timing with high robustness against common-mode transients and other disturbances.

Frequency shift keying (FSK) is a frequency modulation scheme in which data is encoded on a carrier signal by shifting the frequency of the carrier between different frequencies. FSK modulation schemes prove to be extremely robust against CMTI disturbances, since CMTI has a predominant effect on the amplitude of the carrier signal, and minimal impact on the frequency of the carrier signal.

However, demodulator circuits for FSK communication schemes are more complex, and may have higher current consumption, than demodulator circuits for pulsed communication or amplitude shift keying (ASK) communication schemes. and higher complexity of the demodulator circuit. That is, existing circuits for FSK demodulation usually require reference clock signals and increase circuit complexity. This renders state-of-the-art circuits power consuming and complex.

Accordingly, there exists a need for improved circuits and methods for FSK-based communication.

### SUMMARY

According to one aspect, there is provided a circuit for demodulating a frequency shift keying (FSK) modulated signal.

The circuit includes an input node configured to receive an FSK modulated signal. The circuit also includes a phase-voltage converter (PVC) unit including a first PVC input node connected to the input node, a second PVC input node, and a PVC output node. The PVC unit is configured to provide a control signal to the PVC output node based on a phase difference between the FSK modulated signal and a signal on the second PVC input node. The circuit further includes a voltage controlled delay line (VCDL) unit including a first VCDL input node connected to the input node, a second VCDL input node connected to the PVC output node, and a VCDL output node. The VCDL unit is configured to adjust a phase of the FSK modulated signal based on the control signal to produce an adjusted signal, and to provide the adjusted signal to the VCDL output node. The second PVC input node is connected to the VCDL output node. Additionally, the circuit includes an output node connected to the PVC output node, and configured to provide an FSK demodulated signal.

According to another aspect of the present disclosure, there is provided an isolation circuit including an isolation barrier separating a first side from a second side, a first signal modulator configured to generate an FSK modulated signal on the first side of the isolation barrier, and a communication means configured to communicate the FSK modulated signal across the isolation barrier. The isolation circuit also includes a first demodulation circuit provided on the second side of the isolation barrier, the first demodulation circuit configured as described above.

According to a further aspect of the present disclosure, a method for demodulating an FSK modulated signal is provided. The method includes receiving an FSK modulated signal, providing a control signal based on a phase difference between the FSK modulated signal and a further signal, and adjusting a phase of the FSK modulated signal based on the control signal. The further signal is the adjusted signal. The method also includes outputting a demodulated FSK signal based on the control signal.

According to yet another aspect of the present disclosure, there is provided a method for communicating data across an isolation barrier separating a first side from a second side. The method includes generating an FSK modulated signal on the first side of the isolation barrier, communicating the FSK modulated signal across the isolation barrier, and demodulating the FSK modulated signal on the second side of the isolation barrier as described above.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 presents a diagram of a circuit for demodulating a frequency shift keying (FSK) modulated signal according to an implementation;

FIG. 2 presents a diagram of a circuit for demodulating an FSK modulated signal according to another implementation;

FIG. 3 presents a diagram of a circuit for demodulating an FSK modulated signal according to a further implementation;

FIG. 4 presents a diagram of an isolation circuit comprising an isolation barrier and a means for one-way communication of data over the isolation barrier according to an implementation;

FIG. 5 presents a diagram of an isolation circuit including a means to communicate data over the isolation barrier according to another implementation;

FIG. 6 presents a diagram of an isolation circuit including a means for two-way communication of data over the isolation barrier according to a further implementation;

FIG. 7 presents a diagram of an isolation circuit comprising an isolation barrier according to an implementation;

FIG. 8 presents a diagram of an isolation circuit and a means to communicate data over the isolation barrier via two different channels according to an implementation;

FIG. 9 presents a diagram of an isolation circuit and a means to communicate data over the isolation barrier via two different channels according to another implementation;

FIG. 10 presents a flow diagram of a method for demodulating an FSK modulated signal according to an implementation; and

FIG. 11 presents a flow diagram of a method for communicating data across an isolation barrier according to an implementation.

### DETAILED DESCRIPTION

The disclosed concepts relate to a circuit and method for demodulating a frequency shift keying (FSK) modulated signal. The circuit for demodulating the FSK signal comprises an input node configured to receive an FSK modulated signal, and a phase-voltage converter (PVC) unit comprising a first PVC input node connected to the input node, a second PVC input node, and a PVC output node. The PVC unit is configured to provide a control signal to the PVC output node based on a phase difference between the FSK modulated signal and a signal on the second PVC input node. The demodulating circuit further comprises a voltage controlled delay line (VCDL) unit comprising a first VCDL input node connected to the input node, a second VCDL input node connected to the PVC output node, and a VCDL output node. The VCDL unit is configured to adjust a phase of the FSK modulated signal based on the control signal to produce an adjusted signal, and to provide the adjusted signal to the VCDL output node. The second PVC input node is connected to the VCDL output node. The demodulating circuit also comprises an output node connected to the PVC output node, which is configured to provide an FSK demodulated signal.

FSK modulation schemes may be desirable for a wide array of applications, as factors that may cause fluctuations in the amplitude of the modulated signal may not impact the frequency of the signal. Therefore, FSK modulated signals may not be susceptible to certain sources of noise that would otherwise impact other modulated signals, such as amplitude shift keyed (ASK) modulated signals and pulse modulated signals. However, existing circuits for FSK demodulation exhibit high power consumption due to the presence of local oscillators and mixers. In addition, such circuits are typically complex compared to demodulator circuits for ASK modulated signals and pulse modulated signals.

The proposed circuit addresses one or more of the above problems with FSK demodulation circuits by providing a simple and low-power consumption circuit capable of demodulating FSK signals in an asynchronous manner. Specifically, a VCDL unit is utilized to apply a delay to the FSK modulated signal based on a control signal produced by a PVC unit. The PVC unit generates the control signal based on a phase difference between the FSK modulated signal and the signal generated by the VCDL unit. This produces a stable feedback that identifies instances where the FSK modulated signal varies in frequency, thus demodulating the FSK modulated signal.

Accordingly, a delay-locked loop (DLL) circuit may be used to directly demodulate the FSK modulated signal. DLLs may be used to align the phase of an output signal to an input or reference signal without using an oscillator. For example, they can be used to produce different clocking signals, at various frequencies, all of which are synchronized. As a result, DLLs are sometimes used in existing frequency demodulators to synchronize the signal to an internal reference. However, they have not been used as the main demodulating block providing a demodulated FSK signal from a modulated FSK signal.

Usually, the output of the DLL is the adjusted signal produced by the VCDL unit. In contrast, the signal of interest produced by the proposed circuit is the control signal generated by the PVC unit. It has been realized that this control signal contains demodulated information related to the FSK modulated signal. In other words, the control signal is essentially an FSK demodulated signal.

The proposed circuit has a variety of advantages over existing FSK demodulation circuits. Firstly, as the proposed demodulation circuit is capable of demodulating the FSK modulated signal at radio frequencies, down conversion is not required. That is, the FSK modulated signal does not require pre-processing to lower frequencies before demodulation, as the proposed demodulation circuit can demodulate the FSK modulated signal at radio frequencies. This reduces the complexity and cost of the circuit, whilst minimizing power consumption. Nevertheless, if desired, down-conversion can be introduced.

Furthermore, the lack of mixers and local oscillators required by the proposed demodulation circuit enables lower current consumption. Mixers and local oscillators, which are required for other FSK demodulation schemes (e.g., utilizing phase locked loops), consume large amounts of power. The proposed demodulation circuit obviates the need for these components. As a result, the proposed circuit may exhibit low power consumption.

In addition, the proposed demodulator circuit is asynchronous. This means that synchronizing of the demodulator to the FSK modulated signal may not be required in order to demodulate the signal. Once again, this increases simplicity of the proposed circuit, as well as cost and potential power consumption.

The stability of the demodulator circuit is also improved compared to other FSK demodulation schemes. That is, the stability condition of the demodulator circuit is more relaxed (e.g., the demodulator circuit may act predictably over a wider range of operating conditions) than other FSK demodulation means, such as phase locked loops.

In some implementations, the PVC unit may comprise a phase frequency detector (PFD) unit configured to receive the FSK modulated signal and the adjusted signal, and to output an error signal indicating which of the FSK modulated signal and the adjusted signal is leading. The PVC unit may also comprise a low pass filter arrangement configured to receive the error signal, and output the control signal based on the error signal.

One option to implement the PVC unit capable of generating a control signal for controlling the VCDL unit based on the phase difference between the FSK modulated signal and the adjusted signal from the VCDL unit is a PFD unit that detects the phase difference between the signals to produce an error signal (e.g., a signal indicating whether the adjusted signal is lagging or leading the FSK modulated signal), and a low pass filter arrangement that generates a control signal based on the error signal.

To be clear, a first signal “leading” a second signal in this context indicates that the first signal rises or falls before the second signal. If both signals match at all time points, then they are in phase. If they do not match at all time points, then one signal is phase shifted with respect to the other signal. If the phase shift is such that the second signal rises or falls before the first signal, then the second signal is leading the first signal. If the phase shift is such that the first signal rises or falls before the second signal, then the first signal is leading the second signal.

The error signal may be further indicative of how much one signal is leading the other signal. In other words, the error signal may be indicative of an extent of the phase shift between the two signals. To this end, the PFD unit may be configured to receive the FSK modulated signal and the adjusted signal, and to output an error signal indicating which of the FSK modulated signal and the adjusted signal is leading and by how much.

The PFD unit detects which of the FSK modulated signal and adjusted signal is leading the other, and outputs an error signal indicating this. The low pass filter then translates this error signal into a control signal for the VCDL unit, such that the VCDL unit adjusts the incoming FSK modulated signal by shifting the signal appropriately.

In an implementation, the low pass filter arrangement may be configured to output the control signal by sourcing or sinking current based on the error signal.

In one example, the low pass filter arrangement may comprise a capacitor connected between the second VCDL input node and a reference potential node, and a charge pump unit configured to receive the error signal, and to charge and discharge the capacitor based on the received error signal.

For example, if the error signal indicates that the FSK signal leads the adjusted signal, then the low pass filter may sink current (e.g., to a capacitor) thereby causing the VCDL unit to adjust the phase of the FSK modulated signal on the first VCDL input node to decrease the phase difference between these signals. If the error signal indicates that the adjusted signal leads the FSK modulated signal, then the low pass filter may source current (e.g., from a capacitor) thereby causing the VCDL unit to adjust the phase of the FSK modulated signal on the first VCDL input node to decrease the phase difference between these signals.

Furthermore, the PFD unit may be configured to compare the FSK modulated signal and the adjusted signal to generate a comparison result, and to output the error signal based on the comparison result. Then, responsive to the FSK modulated signal leading compared to the adjusted signal, the error signal output by the PFD unit may have a first value. Alternatively, responsive to the FSK modulated signal lagging compared to the adjusted signal, the error signal output by the PFD unit may have a second value.

Thus, the PFD unit either outputs the error signal with a first value or with a second value depending on which of the FSK signal and the adjusted signal are leading with respect to the other. This means that the low pass filter arrangement may either be controlled, by the error signal, to be in a first state or a second state to control the VCDL to adjust the FSK modulated signal on the first VCDL input node.

In an example, the first value may be a value having a first sign (e.g., may be a positive value), and the second value may be a value having a second sign (e.g., may be a negative value). The first value may be the negative of the second value. For instance, the first value may be +1 and the second value may be −1. The extent of the phase shift between the FSK modulated signal and the adjusted signal may be indicated by how long the error signal has the first value (e.g., has a positive value) and how long the error signal has the second value (e.g., the negative value).

In some implementations, the VCDL unit may comprise a fixed delay portion configured to adjust the FSK modulated signal according to a predetermined phase delay to generate an intermediate signal. The VCDL unit may also comprise a variable delay portion configured to adjust the intermediate signal based on the control signal.

A maximum delay applied by the VCDL unit to the FSK modulated signal may be less than twice the period of the FSK modulated signal.

In this way, false locking may be avoided. That is, if the delay applied by the VCDL unit exceeds twice the period of the FSK modulated signal, the circuit may lock onto undesirable frequencies, which may cause the circuit to operate improperly. Therefore, to avoid this result, the maximum delay applicable by the VCDL unit may be fixed at slightly less than twice the period of the FSK modulated signal.

The circuit may also comprise an output conversion arrangement configured to receive the control signal from the PVC output node, and generate the FSK demodulated signal. This component essentially translates the control signal to the demodulated signal from an analog form to a digital form.

More particularly, the output conversion arrangement may comprise a comparator configured to compare the control signal to a threshold voltage to generate a comparison result. In this case, the FSK demodulated signal may be generated based on the comparison result.

The comparator converts the control signal to a digital demodulated FSK signal by comparing the signal to a threshold voltage. In some cases, the threshold voltage may be adjustable to account for variable operating conditions of the circuit.

The disclosed concepts further relate to an isolation circuit that utilizes the disclosed FSK demodulation circuit. In other words, the proposed FSK demodulation circuit may be used to demodulate an FSK modulated signal that is communicated over an isolation barrier. This demonstrates one particular use of the proposed FSK demodulation circuit that utilizes advantages of the FSK communication channel effectively. Nevertheless, it will be readily appreciated that the FSK demodulation circuit may be used in a wide variety of applications.

In particular, the isolation circuit comprises an isolation barrier separating a first side from a second side. The isolation circuit also comprises a first signal modulator configured to generate an FSK modulated signal on the first side of the isolation barrier, and a communication means configured to communicate the FSK modulated signal across the isolation barrier. The isolation circuit further comprises a first demodulation circuit configured to demodulate the FSK modulated signal as described herein. The first demodulation circuit is provided on the second side of the isolation barrier.

The disclosed isolation circuit provides for an alternative means for communicating data over an isolation barrier. This may be useful where a decoupling between the first side and second side is required, but a communication link is still desired. For instance, some gate drivers require isolation between a chip controlling requesting/prompting switching of a gate, and a chip driving the gate. Such gate drivers may include sensors and/or configurable features with a wide range of communication requirements. For example, a sensor located on the output chip may have to communicate back to the input chip to further signal information to a system controller.

Accordingly, it is proposed to utilize FSK modulation to transmit data over the isolation barrier. This is facilitated by the disclosed FSK demodulation circuit, which as explained above, enables demodulation of FSK modulated signals with low power consumption and complexity.

In some implementations, the communication means may comprise a transformer. In this case, the isolation barrier may be formed between a first winding of the transformer and a second winding of the transformer.

In other words, a transformer is provided which isolates a first side (where the first winding is situated) and a second side (where the second winding is situated) is provided. Information may be communicated from the first side to the second side, and vice versa, by the magnetic coupling of the first winding to the second winding, whilst galvanically isolating the first side from the second side.

In alternative implementations, the communication means may comprise a capacitor. The isolation barrier may be formed between a first plate of the capacitor and a second plate of the capacitor.

The capacitor thus isolates a first side (where one surface/plate of the capacitor is situated) from a second side (where another surface/plate of the capacitor is situated). Information may be communicated from the first side to the second side, and vice versa, by the electric coupling of the first plate and the second plate, whilst galvanically isolating the first side from the second side.

Furthermore, the communication means may comprise an oscillator (e.g., a resonating oscillator comprising a resonating tank, also known as a resonant tank) configured to generate a carrier signal oscillating at a predetermined frequency (e.g., an oscillating carrier signal).

The carrier signal is generated, upon which the FSK modulated signal may be transmitted across the isolation barrier. That is, the carrier signal is generated so as to oscillate at a predetermined frequency across the isolation barrier. The first signal modulator modulates the carrier signal. When demodulated, the data encoded onto the carrier signal by the first signal modulator may be determined.

In some implementations, the first signal modulator comprises a variable reactive load configured to alter the (predetermined) frequency of the oscillating carrier signal.

For example, the first signal modulator may comprise an element with a controllable capacitance or a variable inductance. The capacitance or inductance of the element may therefore be controlled to alter the frequency of the oscillating carrier signal according to data to be transmitted across the isolation barrier.

In addition, the isolation circuit may comprise an output comparator connected between the second side of the isolation barrier and the first demodulation circuit. The output comparator may be configured to transform the FSK modulated signal into a square wave having a same frequency as the FSK modulated signal.

In this way, the output comparator acts as an input buffer for the first demodulation circuit, discretizing the signal on the second side of the isolation barrier into a square wave signal.

In some implementations, the isolation circuit may further comprise a second signal modulator configured to generate an ASK modulated signal on the second side of the isolation barrier. In this case, the communication means may be further configured to communicate the ASK modulated signal across the isolation barrier. The isolation circuit may also comprise a second demodulation circuit configured to demodulate the ASK modulated signal, the second demodulation circuit provided on the first side of the isolation barrier.

As a result, there are two different signals provided across the same isolation barrier, with data being transmitted from the first side to the second side, and from the second side to the first side. It is noted that a signal may be both ASK modulated and FSK modulated. ASK modulation has little impact on the frequency of the signal, and FSK modulation has little impact on the amplitude of the signal. Thus, both can be superimposed onto a same carrier signal, enabling two asynchronous communication channels on a same signal. Therefore, this isolation circuit enables simultaneous bi-directional communication between the first side and the second side of the isolation barrier.

To be clear, FSK modulation may be used in conjunction with other modulation schemes to essentially provide two communication channels via a same medium that do not interact with each other. The communication means may thus communicate the FSK modulated signal and the ASK modulated signal via a single medium.

Taking the example of the gate driver above, it may be necessary to communicate information from an input chip to an output chip and vice versa. Gate drive information may need to be communicated from the input chip to the output chip, whilst the output chip may need to provide information from sensors of the gate drive. Whilst all this information may be sent via a same channel, the additional information would require synchronization with the gate drive control signal, and comes at the cost of propagation delay of the gate drive control signal due to time interleaving. Alternatively, a different isolation barrier may be utilized for transmission of this additional information, but will necessarily require more space, increased cost, and increased complexity. If these tradeoffs cannot be tolerated, an alternative means for communicating data over the isolation barrier is required. It is therefore proposed to utilize both ASK modulation and FSK modulation to communicate information asynchronously.

As bidirectional communication with full duplex communication at the same time over one isolation barrier is enabled, the compromise between propagation delay and additional cost/area is obviated. Indeed, by use of the FSK demodulator circuit disclosed herein, this may be achieved without excessive power consumption or complexity.

In some cases, the isolation circuit may further comprise a second signal modulator configured to generate an ASK modulated signal on the first side of the isolation barrier. In this case, the communication means may be further configured to communicate the ASK modulated signal across the isolation barrier. The isolation circuit may also comprise a second demodulation circuit configured to demodulate the ASK modulated signal, the second demodulation circuit provided on the second side of the isolation barrier.

That is, it may be the case that both the first and second signal modulators are provided on a same side of the isolation barrier, and the first and second demodulation circuits are provided on the opposite side of the isolation barrier. Whilst this does not allow bi-directional communication, it provides two different communication channels over the same isolation barrier. This may be particularly useful if, for example, two streams of asynchronous information are to be communicated from one side of the isolation barrier to the other. Taking the gate driver example above, this may be the case if the input chip needs to provide a gate drive signal to the output chip, whilst also communication configuration information for reconfiguration of the output chip.

In some implementations, the second signal modulator comprises a variable biasing current source configured to alter an amplitude of the oscillating carrier signal. Alternatively, or additionally, the second signal modulator comprises a variable resistor configured to alter an amplitude of the oscillating carrier signal.

Both the variable biasing current source and variable resistor are capable of altering an amplitude of the oscillating carrier signal. These elements are controllable, thus implementing ASK modulation of the oscillating carrier signal. That is, the elements may be controlled to transmit data via ASK modulation.

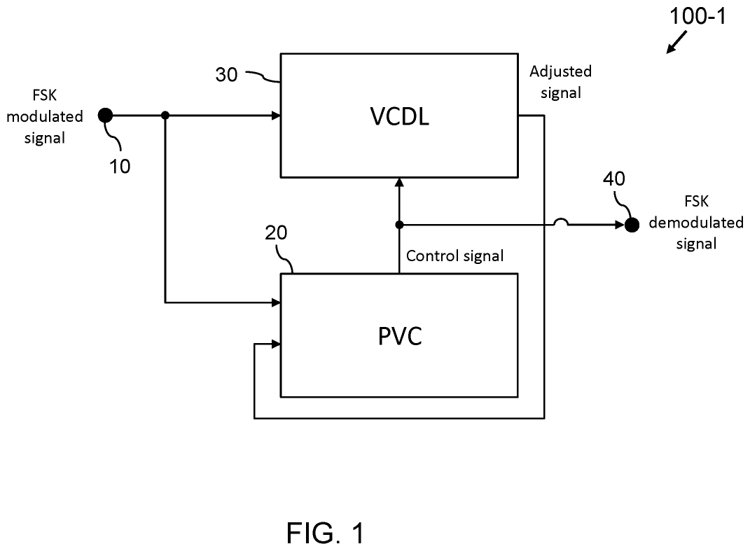

FIG. 1 presents a diagram of a circuit 100-1 for demodulating an FSK modulated signal according to an implementation. The circuit comprises a VCDL unit 30 and a PVC unit 20.

Generally, a VCDL unit 30 is a circuit that delays a digital signal. The amount of delay is a function of an input control voltage provided by a control signal. In this case, the VCDL unit 30 is configured to adjust a phase of an input signal based on a control signal to produce an adjusted signal. That is, the VCDL unit 30 may increase or decrease a phase of an input signal depending on the control signal applied to the VCDL unit 30.

A PVC unit 20 compares the phase difference of a first input signal and a second input signal, and generates an output based on the phase difference between the first input signal and the second input signal. Specifically, the PVC unit 20 compares the phase difference between rising edges of the first input signal and the second input signal. The PVC unit 20 thereby generates a control signal based on the phase difference between the two input signals.

The input node 10 of the circuit 100-1 receives an FSK modulated signal. That is, the input node 10 is configured to obtain a signal that has been FSK modulated, such that the signal has information encoded onto it by shifting of the frequency of the signal. These shifts in frequency correspond to data to be demodulated/extracted from the FSK modulated signal by the circuit 100-1.

The PVC unit 20 comprises a first PVC input node connected to the input node 10, a second PVC input node connected to a VCDL output node, and a PVC output node. Thus, the PVC unit 20 is configured to provide a control signal to the PVC output node based on a phase difference between the FSK modulated signal (e.g., the signal on the first PVC input node) and a signal on the second PVC input node (e.g., the adjusted signal from the VCDL unit 30).

The VCDL circuit comprises a first VCDL input node connected to the input node 10. The VCDL circuit also comprises a second VCDL input node connected to the PVC output node. The VCDL unit 30 further comprises a VCDL output node. The VCDL unit 30 configured to adjust a phase of the FSK modulated signal (e.g., the signal on the first VCDL input node) based on the control signal (e.g., the signal received on the second VCDL input node) to produce an adjusted signal. The VCDL unit 30 is configured to provide the adjusted signal to the VCDL output node.

To be clear, the VCDL output node and the second PVC input node are connected. The PVC output node and the second VCDL input node are connected. The PVC unit 20 detects a phase shift between the FSK modulated signal and the output of the VCDL unit 30. The VCDL shifts the phase of the FSK modulated signal on the input node 10, and sends this adjusted signal to the second PVC input node. The frequency of the signal on the input node 10 and the signal on the VCDL output node is always the same, even when the input signal frequency (e.g., the frequency of the FSK modulated signal) is changed. However, when the input signal frequency is changed, the phase between the signal on the input node 10 and the signal on the VCDL output node is shifted.

The control signal from the PVC unit 20 controls the delay time implemented by the VCDL unit 30. For different frequencies, a specific delay time will show up as two different phase shifts applied to the signals of two different frequencies. Thus, the circuit 100-1 aims to shift the FSK modulated signal provided to the VCDL unit 30 by one cycle. For different frequencies, different delay times thus need to be applied by the VCDL unit 30. As a result, the control signal input provided to the VCDL unit 30 must be different. This control signal (on output node 40) therefore relates to the frequency of the FSK modulated signal. This signal can therefore be used as the demodulated version of the FSK modulated input signal.

Accordingly, the circuit 100-1 further comprises an output node 40 connected to the PVC output node, and configured to provide an FSK demodulated signal. Therefore, unlike a typical DLL where the output signal is the phase shifted adjusted signal output by the VCDL, the output signal is the control signal, which may be considered an FSK demodulated signal.

In other words, normally in such a circuit, the input is the signal on the input node, and the output signal is the output of the VCDL unit 30 (e.g., the signal on the VCDL output node, or the adjusted signal). The aim of such a circuit is to synchronize the output with the input. In contrast, in the case of the present circuit 100-1, the output signal is the control signal, which proves to be the demodulated information coming from the FSK modulated signal.

For the present circuit 100-1, the input FSK modulated signal is fed to a PVC, which senses the phase difference between the FSK modulated signal, and a delayed version of it from the VCDL unit 30 (e.g., the adjusted signal) and produces a control signal that controls the delay produced by the VCDL unit 30 on the incoming FSK modulated signal when generating the adjusted signal.

As a result, if the circuit 100-1 is correctly tracking the FSK modulated signal, the control signal represents the output of the FSK demodulator, effectively being an analog version of the demodulated received signal.

In some implementations, the circuit 100-1 may further comprise an output conversion arrangement configured to receive the control signal from the PVC output node, and generate the FSK demodulated signal. This may convert the control signal into a different form than the control signal. For instance, this may convert the control signal to a digital form. Thus, in other words, the output conversion arrangement may be an analog-to-digital converter (ADC)

More particularly, the output conversion arrangement may comprise a comparator configured to compare the control signal to a threshold voltage to generate a comparison result. The FSK demodulated signal is then generated based on the comparison result. That is, if the control signal meets or exceeds a threshold voltage, the comparator may output a high signal, and if the control signal fails to meet a threshold voltage, the comparator may output a low signal. The resulting signal stream will therefore be a digitized version of the FSK demodulated signal. This threshold voltage may be configurable, and therefore may be adjusted for the given application.

In some implementations, the VCDL unit 30 is formed of two delay blocks. The VCDL unit 30 may thus comprise a fixed delay portion configured to adjust the FSK modulated signal according to a predetermined phase delay to generate an intermediate signal, and a variable delay portion configured to adjust the intermediate signal based on the control signal. The fixed delay portion thus delays the input signal by a fixed amount, whilst the variable delay portion delays the input signal by a controllable amount depending on the control signal. The fixed delay portion is provided to introduce calibration/trimming capabilities to compensate for process variations. Both delay portions may comprise chains of starved current delay cells. The cells of the fixed delay are biased with a constant fixed current, the cells of the variable delay instead are biased with a current proportional to a control voltage provided by the control signal.

The maximum delay applied by the VCDL is slightly lower than twice the input period in order to avoid false locking.

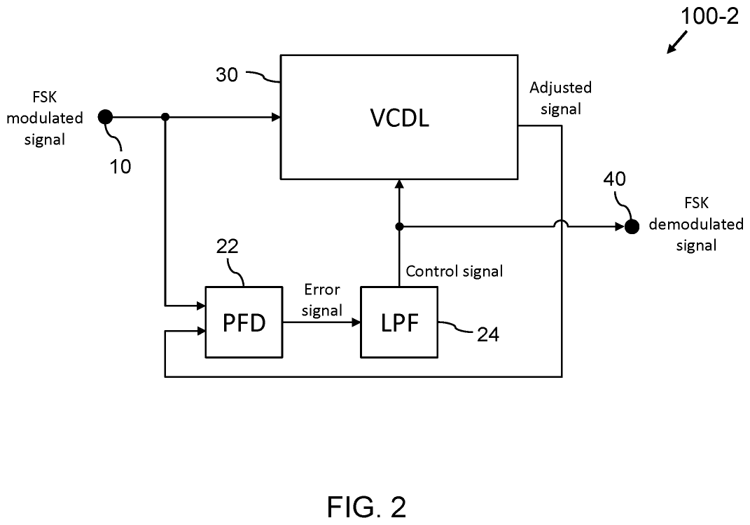

FIG. 2 presents a diagram of a circuit 100-2 for demodulating an FSK modulated signal according to another implementation. Specifically, the circuit 100-2 of FIG. 2 is similar to the circuit 100-1 of FIG. 1, with the PVC 20 implemented by a PFD unit 22 and a low pass filter arrangement 24. Therefore, repeated description of much of the circuit is omitted here for sake of brevity.

The PFD unit 22 is configured to receive the FSK modulated signal and the adjusted signal, and to output an error signal indicating which of the FSK modulated signal and the adjusted signal is leading. That is, the PFD compares the phase difference of two input signals on the first PVC input node and the second PVC input node (e.g., the FSK modulated signal and the adjusted signal), and produces an error signal.

In some implementations, the PFD unit 22 is configured to compare the FSK modulated signal and the adjusted signal, and to output the error signal based on a result of the comparison. When the FSK modulated signal leads compared to the adjusted signal, the error signal output by the PFD unit 22 has a first value or first sign. When the FSK modulated signal lags compared to the adjusted signal (e.g., the adjusted signal leads the FSK modulated signal) the error signal output by the PFD unit 22 has a second value or second sign. The first value may be a high signal, and the second value may be a low signal, or vice versa. The first value may be a positive signal, and the second value may be a negative signal, or vice versa.

In other words, the PFD unit 22 compares the phase difference of the FSK modulated signal and the adjusted signal, and produces two output pulsing signals (one for if the FSK modulated signal is leading, and one for if the adjusted signal is leading) whose durations are proportional to the phase difference. For instance, the two output pulsing signals may have differing signs.

In one example, the PFD unit 22 may be formed of two flip-flops and a delayed reset circuit. The main requirement on the PFD unit 22 is response speed in order for the feedback loop to react as quickly as possible to frequency changes of the FSK modulated signal. To this end, the flip-flops may be implemented using true single-phase clock (TSPC) logic. TSPC logic enables high speed, reduced area and reduced current consumption.

The low pass filter arrangement 24 is configured to receive the error signal, and output the control signal based on the error signal. In essence, the low pass filter arrangement 24 converts the error signal from the PFD unit 22 (which describes the phase difference between the FSK modulated signal and the adjusted signal) into a control signal for controlling the VCDL unit 30 to delay the incoming FSK modulated signal to generate a further adjusted signal. To this end, the low pass filter arrangement 24 may be configured to output the control signal by sourcing or sinking current based on the error signal. This may adjust a voltage on the second VCDL input node, therefore changing an amount of delay applied by the VCDL unit 30 to the FSK modulated signal.

That is, the error signal fed to the low pass filter arrangement 24 and converted to a control signal having a variable control voltage by the low pass filter arrangement 24. The control voltage of the control signal controls the delay produced by the VCDL unit 30, in order to adjust the phase of the adjusted signal to lock it to the input FSK modulated signal.

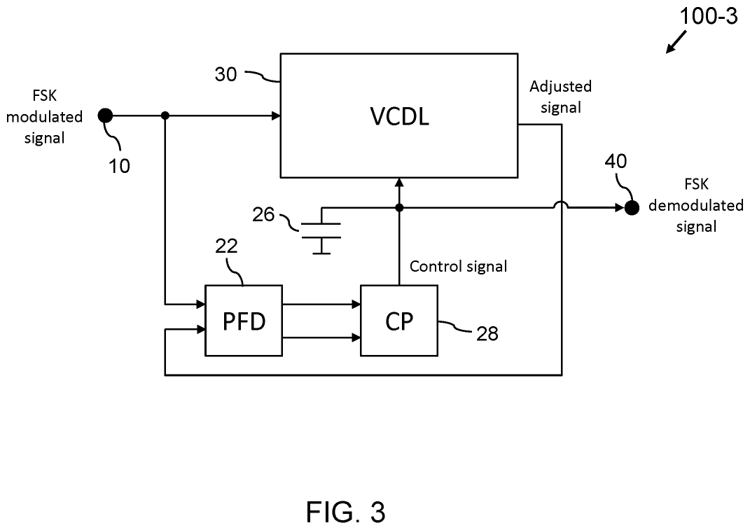

FIG. 3 presents a diagram of a circuit for demodulating an FSK modulated signal according to a further implementation. Specifically, the circuit of FIG. 3 shows one implementation of the low pass filter arrangement 24 of FIG. 2. Repeated description of other components is omitted here for sake of brevity.

Specifically, the low pass filter arrangement 24 comprises a charge pump 28 and a capacitor 26. The capacitor 26 is connected between the second VCDL input node and a reference potential node (e.g., a ground potential). The charge pump 28 is configured to receive the error signal, and to charge and/or discharge the capacitor 26 based on the received error signal.

Accordingly, the charge pump 28 converts the information about the phase error coming from the PFD unit 22 into a voltage. The error signal having a first value or first sign may cause the charge pump 28 to charge the capacitor 26, and the error signal having a second value or second sign may cause the charge pump 28 to discharge the capacitor 26 (or vice versa), for example. The voltage across the capacitor 26 controls the delay applied by the VCDL unit 30.

Of course, it will be appreciated that the VCDL unit 30 and/or the PVC unit 20 may be built using alternative components depending on the desired trade-off between stability, cost, size and power consumption.

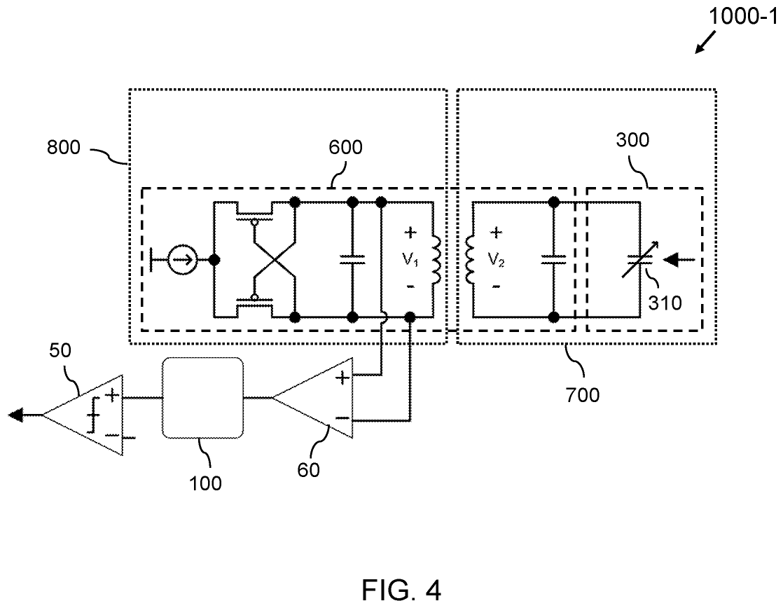

FIG. 4 presents a diagram of an isolation circuit 1000-1 comprising an isolation barrier and a means for one-way communication of data over the isolation barrier according to an implementation. This essentially presents one use of the FSK demodulation circuit described above.

As shown, the isolation circuit 1000-1 comprises an isolation barrier separating a first side 700 from a second side 800. The isolation barrier may be galvanic, meaning that no DC components are transferred between the first side 700 and the second side 800 of the isolation barrier, whilst AC components may be communicated. This isolation may protect one side from events (e.g., voltage or current peaks) on the other side.

In the depicted case, the isolation barrier is formed between a first winding and a second winding of a transformer. The physical gap between the first winding and the second winding of the transformer therefore provides the decoupling/isolation of the first side 700 from the second side 800, whilst the magnetic coupling of the first winding and the second winding provides a means to communicate information over the isolation barrier. In some implementations, the transformer may be coreless (e.g., it may have an air core, or a core formed of a material with similarly low dielectric permittivity).

Nevertheless, various different isolation mechanisms may be employed. In another example, the isolation barrier may be formed between a first plate and a second plate of a capacitor. The gap between the first plate and second plate therefore provides the decoupling/isolation of the first side 700 from the second side 800. The electric coupling of the first plate and the second plate of the capacitor may nevertheless allow communication across the isolation barrier.

The isolation circuit 1000-1 further comprises a communication means 600 configured to communicate the FSK modulated signal across the isolation barrier.

In the depicted case, the communication means 600 comprises an oscillator (e.g., a resonating oscillator comprising a resonating tank) configured to generate a carrier signal oscillating at a predetermined frequency. That is, the oscillator creates an oscillating carrier signal at a predetermined frequency (e.g., a radio frequency). The carrier signal is communicated across the isolation barrier by the transformer. The oscillator in the depicted example includes the inductances of the transformer, and the capacitors provided in parallel with the windings of the transformer. There is further provided a current source acting as a biasing stage, and a cross-coupled pair/negative gm assembly. The current source and negative gm assembly are therefore provided to sustain oscillation of the carrier signal.

Thus, the oscillator built around the transformer therefore generates an oscillating carrier signal. Indeed, such a circuit leverages the single resonance behavior of the transformer, and a carrier signal is produced and coupled by the transformer to both sides of the isolation barrier. In other words, the transformer acts as the inductive part of the oscillator, whilst the capacitive part of the oscillator is provided by explicit capacitors in parallel to both windings of the transformer.

Furthermore, the isolation circuit 1000-1 comprises a first signal modulator 300 configured to generate an FSK modulated signal on the first side 700 of the isolation barrier. The first signal modulator 300 is provided on the first side 700 of the isolation barrier. For instance, the first signal modulator 300 may encode information onto a carrier signal by shifting the frequency of the carrier signal. For example, the frequency may be shifted between two discrete frequencies according to a stream of bits, with a first frequency representing a first value of the bits, and a second frequency representing a second value of the bits.

In the depicted case, the first signal modulator 300 comprises a variable reactive load 310 configured to alter the frequency of the oscillating carrier signal. The variable reactive load 310 is therefore controlled in order to alter the frequency of the oscillating carrier signal, thus encoding information onto the carrier signal and generating an FSK modulated signal. More specifically, the variable reactive load 310 may include a variable capacitor having a variable capacitance. In other cases, the variable reactive load 310 may include a variable inductor having a variable inductance.

The isolation circuit 1000-1 also comprises a first demodulation circuit 100 on the second side 800 of the isolation barrier. The first demodulation circuit 100 is configured to demodulate the FSK modulated signal. The first demodulation circuit 100 may be any FSK demodulation circuit described herein.

Accordingly, the isolation circuit 1000-1 provides a means for separating a first side 700 from a second side 800, whilst enabling communication of data from the first side 700 to the second side 800. The first signal modulator 300 produces an FSK modulated signal on one side of the isolation barrier, and the first demodulation circuit 100 provides a means for demodulating the FSK modulated signal to determine data transmitted across the isolation barrier.

Furthermore, the isolation circuit 1000-1 may also comprise an output comparator 60 between the second side 800 of the isolation barrier and the first demodulation circuit 100. The output comparator 60 is configured to transform the FSK modulated signal (e.g., the carrier signal that has been encoded with information by switching of the frequency of the carrier signal) into a square wave having a same frequency as the FSK modulated signal.

In other words, the FSK modulated signal is discretized by the output comparator 60, and passed to the first demodulation circuit 100. The output comparator 60 acts as an output buffer configured to convert the FSK modulated signal into a square wave having a same frequency as the FSK modulated signal.

Finally, the isolation circuit 1000-1 comprises an output conversion arrangement 50 configured to receive the control signal from the PVC output node of the first demodulation circuit 100, and generates the FSK demodulated signal. As shown, the output conversion arrangement 50 comprises a comparator configured to compare the control signal to a threshold voltage (which may be configurable), and generates the FSK demodulated signal based on a result of the comparison. Thus, the analog signal produced by the first demodulation circuit 100 is converted to a digital signal.

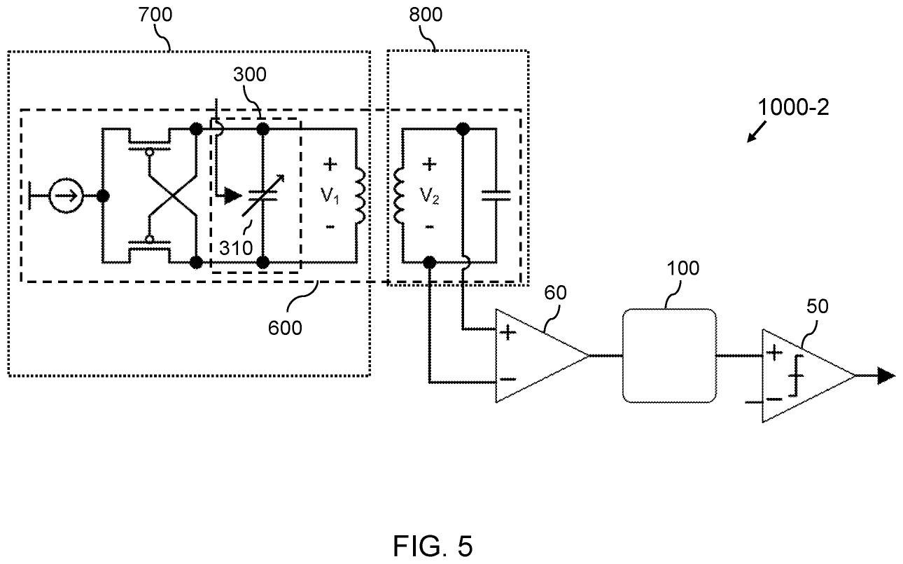

It should be appreciated that the isolation circuit 1000-1 and communication means 600 may be rearranged. This is depicted in FIG. 5, which presents a diagram of an isolation circuit 1000-2 including a means to communicate data over the isolation barrier according to another implementation.

In particular, in contrast to the isolation circuit 1000-1 of FIG. 4, the isolation circuit 1000-2 of FIG. 5 comprises a current source, and a cross-coupled pair/negative gm assembly provided on a first side 700 of the isolation barrier, rather than the second side 800 of the isolation barrier. This means that the variable reactive load 310 of the first signal modulator 300 is on the same side as this assembly, and forms part of the oscillator.

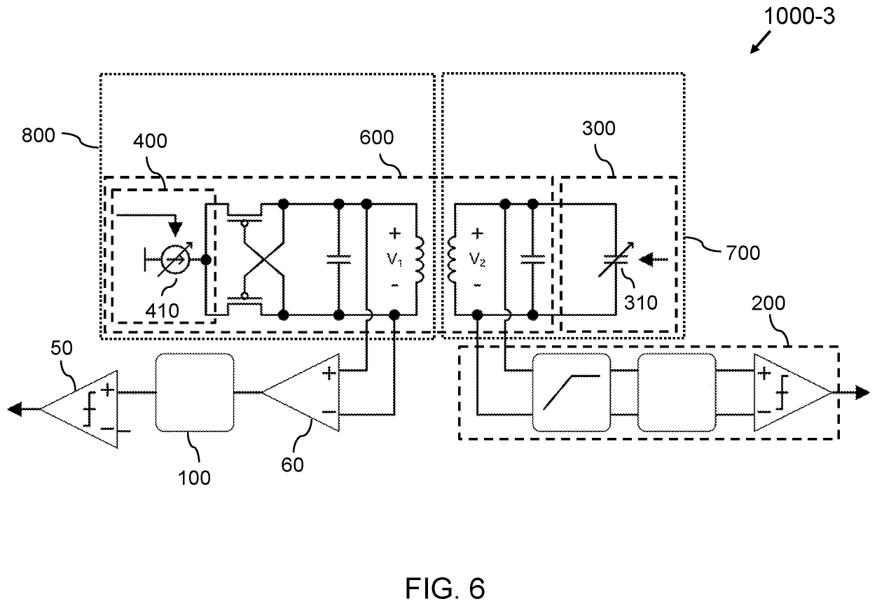

FIG. 6 presents a diagram of an isolation circuit 1000-3 including a means for two-way communication of data over the isolation barrier according to a further implementation. The circuit 1000-3 of FIG. 6 is similar to the circuit 1000-1 of FIG. 4, and therefore repeated description of the isolation barrier, communication means 600, first signal modulator 300, and first demodulation circuit 100 is omitted here for sake of brevity.

In this case, the isolation circuit 1000-3 further comprises a second signal modulator 400 configured to generate an ASK modulated signal on the second side 800 of the isolation barrier. The second signal modulator 400 is provided on the second side 800 of the isolation barrier. For instance, the second signal modulator 400 may encode information onto a carrier signal by adjusting the amplitude of the carrier signal. For example, the amplitude may be shifted between two discrete amplitudes according to a stream of bits, with a first amplitude representing a first value of the bits, and a second amplitude representing a second value of the bits.

In the depicted case, the second signal modulator 400 comprises a variable biasing current source 410 configured to alter the amplitude of the oscillating carrier signal generated by the oscillator. The variable biasing current source 410 is therefore controlled in order to alter the amplitude of the oscillating carrier signal, thus encoding information onto the carrier signal and generating an ASK modulated signal. In the depicted case, the variable biasing current source 410 acts as a biasing stage, alongside the negative gm assembly, ensuring oscillation of the carrier signal.

In other cases, the second signal modulator 400 may comprise a variable resistor, which may be configured to alter the amplitude of the oscillating carrier signal).

The isolation circuit 1000-3 also comprises a second demodulation circuit 200 on the first side 700 of the isolation barrier. The second demodulation circuit 200 is configured to demodulate the ASK modulated signal.

To this end, the second demodulation circuit 200 may comprise a high pass filter that is configured to filter out any CMTI disturbances). The second demodulation circuit 200 may also comprise an envelope detector to demodulate the ASK modulated signal, and a comparator configured to convert the ASK demodulated signal from the envelope detector into a digital signal.

Nevertheless, other circuits capable of demodulating an ASK modulated signal could be implemented in place of the second demodulation circuit 200 depicted in FIG. 6. Such circuits would be readily identified and implemented by the skilled person.

Accordingly, the isolation circuit 1000-3 provides a means for separating a first side 700 from a second side 800, whilst enabling bi-directional communication of data from the first side 700 to the second side 800. As FSK and ASK modulation do not substantially affect each other, both modulation schemes may be applied to a same signal (e.g., a same communication channel) without impacting the other. That is, as altering the frequency of a carrier signal does not substantially impact the amplitude of the carrier signal, and as altering the amplitude of a carrier signal does not substantially impact the frequency of the carrier signal, both means by be used to communicate information across the isolation barrier. This enables bi-directional asynchronous communication with a high bit-rate.

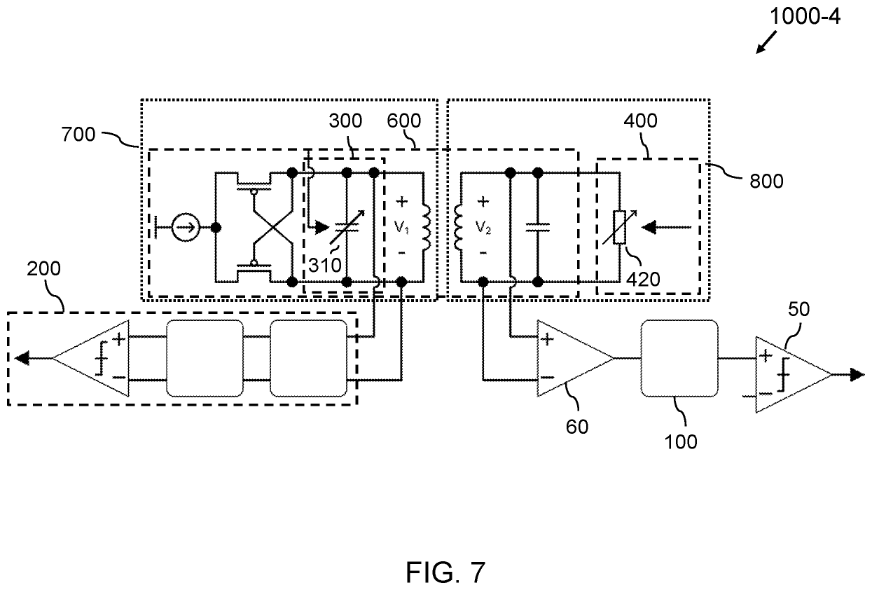

Of course, like above, the oscillator may be rearranged differently to the arrangement of FIG. 6. FIG. 7 presents a diagram of an isolation circuit 1000-4 enabling bi-directional communication according to another implementation.

In contrast to the circuit 1000-3 of FIG. 6, the circuit 1000-4 of FIG. 7 comprises a communication means 600 including a oscillator, wherein a current source and a cross-coupled pair/negative gm assembly are provided on a first side 700 of the isolation barrier, rather than the second side 800 of the isolation barrier. This means that the variable reactive load 310 of the first signal modulator 300 is on the same side as this assembly, e.g., to form part of the oscillator.

In this case, the second signal modulator 400 comprises a variable resistor 420, with a resistance controllable according to a bit stream. The variable resistor 420 adjusts the amplitude of the carrier signal, thus implementing an ASK modulation scheme.

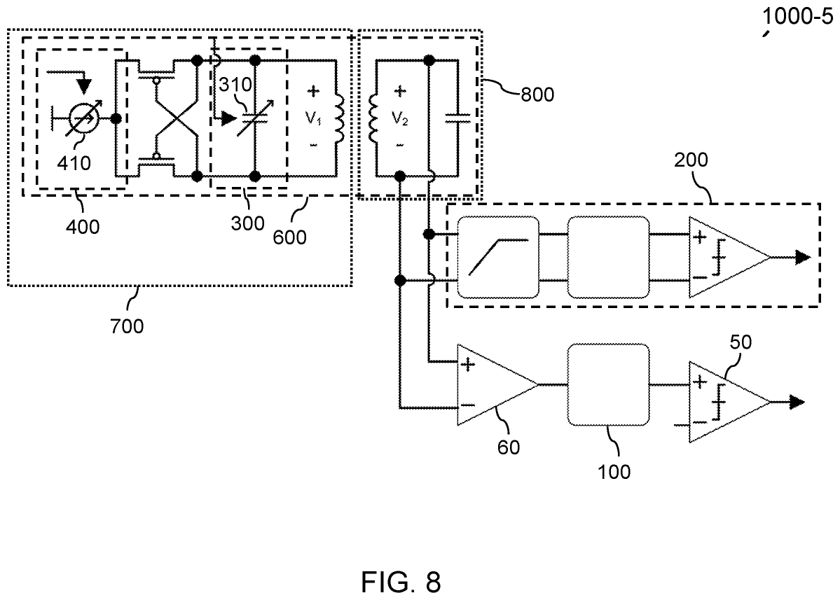

FIG. 8 presents a diagram of an isolation circuit 1000-5 and a means to communicate data over the isolation barrier via two different channels according to an implementation.

In this case, the oscillator (e.g., the negative gm assembly), the first signal modulator 300 and the second signal modulator 400 are each provided on a first side 700 of the isolation barrier. The first variable reactive load 310 and variable biasing current source 410 act as parts of the (e.g., resonating) oscillator. The first demodulation circuit 100 and the second demodulation circuit 200 are provided on the second side 800 of the isolation barrier. Accordingly, communication via two different channels is provided over a single isolation barrier from the first side 700 to the second side 800 of the isolation barrier. This may be useful, for instance, when two asynchronous data streams need to be transmitted from a first side 700 of an isolation barrier to a second side 800 of an isolation barrier.

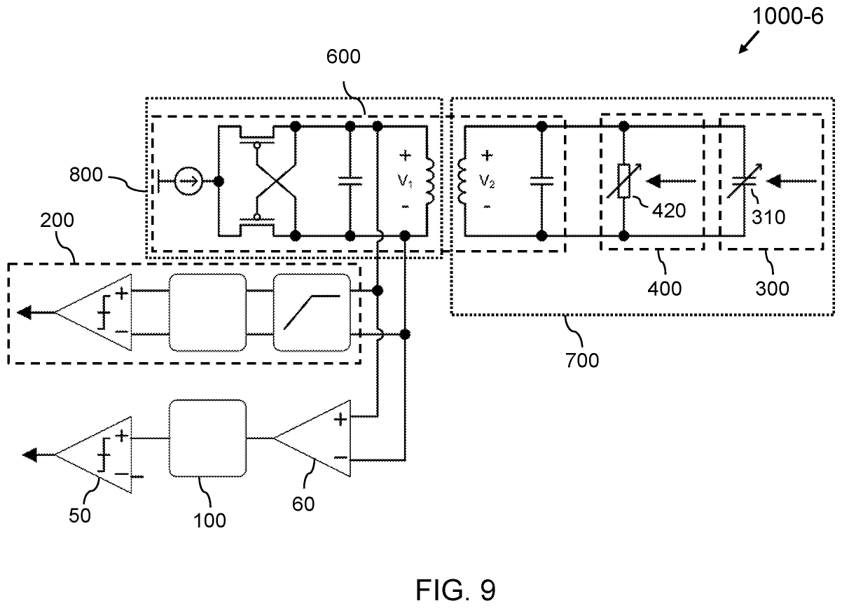

FIG. 9 presents a diagram of an isolation circuit 1000-6 and a means to communicate data over the isolation barrier via two different channels according to another implementation. In this implementation, a biasing current source and negative gm assembly of the oscillator are provided on the second side 800 of the isolation barrier. This operates in substantially the same way as the circuit 1000-5 of FIG. 8.

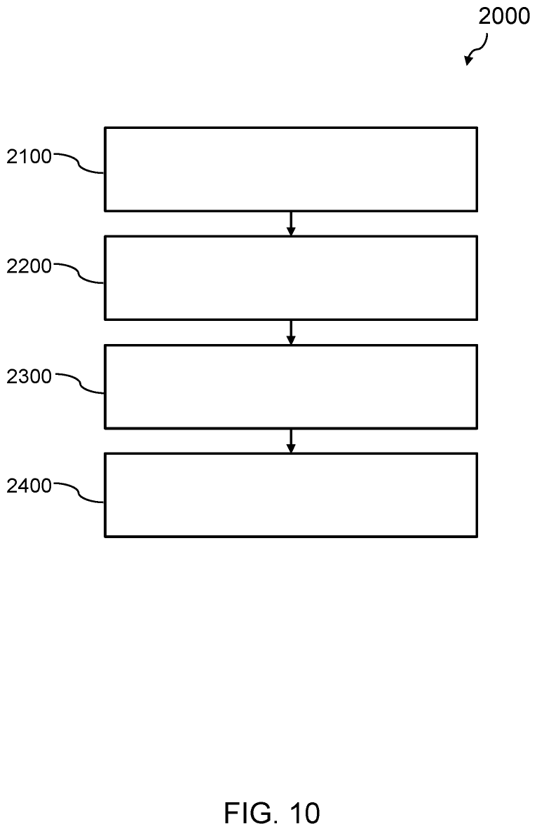

FIG. 10 presents a flow diagram of a method 2000 for demodulating an FSK modulated signal according to an implementation.

In step 2100, an FSK modulated signal is received. The FSK modulated signal may be received on an input node, for example, The FSK modulated signal may be received on a second side of an isolation barrier from a first side of an isolation barrier. To be clear, the FSK modulated signal is an oscillating signal having a frequency, with the frequency of the signal varying. This variation of the frequency indicators data that is encoded into the signal.

In step 2200, a control signal is provided based on a phase difference between the FSK modulated signal and a further signal. That is, a difference in phase between the FSK modulated signal and another signal is assessed, and a control signal generated that may be proportional to this difference. To this end, a phase difference in a rising or falling edge of the FSK modulated signal and the further signal may be detected, and a control signal generated based on this difference.

In step 2300, a phase of the FSK modulated signal is adjusted based on the control signal. The further signal is the adjusted signal. That is, an adjusted signal is generated by adjusting the FSK modulated signal according to the control signal. To this end, the FSK modulated signal may be delayed by an amount dictated by the control signal. The adjusted signal is then provided for comparison with the FSK modulated signal to determine a phase difference between the two signals.

In step 2400, a demodulated FSK signal is output based on the control signal. As described above, the control signal is a demodulated version of the FSK modulated signal. This may be further processed to digitize the control signal to provide the demodulated FSK signal.

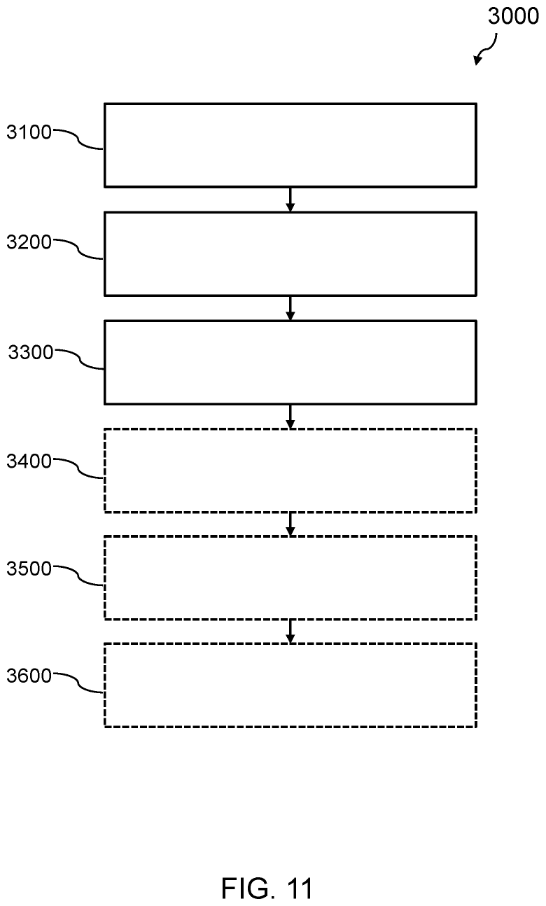

FIG. 11 presents a flow diagram of a method for communicating data across an isolation barrier according to an implementation.

In step 3100, an FSK modulated signal is generated on the first side of the isolation barrier. For example, a carrier signal may be encoded with data by adjusting a frequency of the carrier signal.

In step 3200, the FSK modulated signal is communicated across the isolation barrier. That is, the FSK modulated signal is transmitted across the isolation barrier.

Step 3300 of FIG. 11 relates to method 2000 of FIG. 10. Specifically, in step 3300, the FSK modulated signal is demodulated on the second side of the isolation barrier after being received on the second side of the isolation barrier as described above.

Optionally, method 3000 may further comprise one or more of steps 3400, 3500 and 3600.

In step 3400, an ASK modulated signal is generated on the second side of the isolation barrier. For example, a carrier signal may be encoded with data by adjusting an amplitude of the carrier signal.

In step 3500, the ASK modulated signal is communicated across the isolation barrier. That is, the ASK modulated signal is transmitted across the isolation barrier.

In step 3600, the ASK modulated signal is demodulated on the first side of the isolation barrier. This may be achieved by any known ASK demodulation scheme.

In this way, simultaneous bi-directional asynchronous communication between the first side and second side of the isolation barrier is achieved.

Alternatively, in step 3400, an ASK modulated signal is generated on the first side of the isolation barrier. In this case, in step 3600, the ASK modulated signal is demodulated on the second side of the isolation barrier.

In this way, simultaneous asynchronous communication from the first side to the second side of the isolation barrier of two different data streams is achieved.

Although specific examples have been illustrated and described herein, it will be appreciated by those of ordinary skill in the art that a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

The following implementations are disclosed:
1. A circuit for demodulating a frequency shift keying, FSK, modulated signal, comprising:
an input node configured to receive an FSK modulated signal;
a phase-voltage converter, PVC, unit comprising a first PVC input node connected to the input node; a second PVC input node; and a PVC output node, the PVC unit configured to provide a control signal to the PVC output node based on a phase difference between the FSK modulated signal and a signal on the second PVC input node;
a voltage controlled delay line, VCDL, unit comprising a first VCDL input node connected to the input node; a second VCDL input node connected to the PVC output node; and a VCDL output node, the VCDL unit configured to adjust a phase of the FSK modulated signal based on the control signal, and to provide the adjusted signal to the VCDL output node,
wherein the second PVC input node is connected to the VCDL output node; and
an output node connected to the PVC output node, and configured to provide an FSK demodulated signal.
2. The circuit of implementation 1, wherein the PVC unit comprises:
a phase frequency detector, PFD, unit configured to receive the FSK modulated signal and the adjusted signal, and to output an error signal indicating which of the FSK modulated signal and the adjusted signal is leading; and
a low pass filter arrangement configured to receive the error signal, and output the control signal based on the error signal.
3. The circuit of any one of the previous implementations, wherein the low pass filter arrangement is configured to output the control signal by sourcing or sinking current based on the error signal.
4. The circuit of implementation 3, wherein the low pass filter arrangement comprises:
a capacitor connected between the second VCDL input node and a reference potential node; and
a charge pump unit configured to receive the error signal, and to charge and discharge the capacitor based on the received error signal.
5. The circuit of any one of the previous implementations, wherein the PFD unit is configured to compare the FSK modulated signal and the adjusted signal, and to output the error signal based on a result of the comparison, wherein:
responsive to the FSK modulated signal leading compared to the adjusted signal, the error signal output by the PFD unit has a first value, and
responsive to the FSK modulated signal lagging compared to the adjusted signal, the error signal output by the PFD unit has a second value.
6. The circuit of any one of the previous implementations, wherein the VCDL unit comprises:
a fixed delay portion configured to adjust the FSK modulated signal according to a predetermined phase delay to generate an intermediate signal; and
a variable delay portion configured to adjust the intermediate signal based on the control signal.
7. The circuit of any one of the previous implementations, wherein a maximum delay applied by the VCDL unit to the FSK modulated signal is less than twice the period of the FSK modulated signal.
8. The circuit of any one of the previous implementations, further comprising an output conversion arrangement configured to receive the control signal from the PVC output node, and generate the FSK demodulated signal.
9. The circuit of any one of the previous implementations, wherein the output conversion arrangement comprises a comparator configured to compare the control signal to a threshold voltage, wherein the FSK demodulated signal is generated based on a result of the comparison
10. An isolation circuit, comprising:
an isolation barrier separating a first side from a second side;
a first signal modulator configured to generate an FSK modulated signal on the first side of the isolation barrier;
a communication means configured to communicate the FSK modulated signal across the isolation barrier; and
a first demodulation circuit configured to demodulate the FSK modulated signal according to any of implementations 1-9, the first demodulation circuit provided on the second side of the isolation barrier.
11. The isolation circuit of implementation 10, wherein the communication means comprises a oscillator configured to generate a carrier signal oscillating at a predetermined frequency.
12. The isolation circuit of implementation 11, wherein the first signal modulator (200) comprises a variable reactive load configured to alter the frequency of the oscillating carrier signal.
13. The isolation circuit of any one of the previous implementations, further comprising an output comparator between the second side of the isolation barrier and the first demodulation circuit, the output comparator configured to transform the FSK modulated signal into a square wave having a same frequency as the FSK modulated signal.
14. The isolation circuit of any one of the previous implementations, further comprising:
a second signal modulator configured to generate an amplitude shift keying, ASK, modulated signal on the second side of the isolation barrier, wherein the communication means is further configured to communicate the ASK modulated signal across the isolation barrier; and
a second demodulation circuit configured to demodulate the ASK modulated signal, the second demodulation circuit provided on the first side of the isolation barrier.
15. The isolation circuit of any one of the previous implementations, further comprising:
a second signal modulator configured to generate an ASK modulated signal on the first side of the isolation barrier, wherein the communication means is further configured to communicate the ASK modulated signal across the isolation barrier; and
a second demodulation circuit configured to demodulate the ASK modulated signal, the second demodulation circuit provided on the second side of the isolation barrier.
16. The isolation circuit of any one of the previous implementations, wherein the second signal modulator comprises a variable biasing current source or a variable resistor configured to alter an amplitude of the oscillating carrier signal.
17. The isolation circuit of any one of the previous implementations, wherein the communication means comprises a transformer, and wherein the isolation barrier is formed between a first winding of the transformer and a second winding of the transformer.
18. The isolation circuit of any one of the previous implementations, wherein the communication means comprises a capacitor, and wherein the isolation barrier is formed between a first plate of the capacitor and a second plate of the capacitor.
19. A method for demodulating a frequency shift keying, FSK, modulated signal, comprising:
receiving an FSK modulated signal;
providing a control signal based on a phase difference between the FSK modulated signal and a further signal;
adjusting a phase of the FSK modulated signal based on the control signal, wherein the further signal is the adjusted signal; and
outputting a demodulated FSK signal based on the control signal.
20. A method for communicating data across an isolation barrier separating a first side from a second side, comprising:
generating an FSK modulated signal on the first side of the isolation barrier;
communicating the FSK modulated signal across the isolation barrier; and
demodulating the FSK modulated signal on the second side of the isolation barrier according to implementation 19.
21. The method of implementation 20, further comprising:
generating an amplitude shift keying, ASK, modulated signal on the second side of the isolation barrier;
communicating the ASK modulated signal across the isolation barrier; and
demodulating the ASK modulated signal on the first side of the isolation barrier.
22. The method of implementation 20, further comprising:
generating an amplitude shift keying, ASK, modulated signal on the first side of the isolation barrier;
communicating the ASK modulated signal across the isolation barrier; and
demodulating the ASK modulated signal on the second side of the isolation barrier.

1. A circuit for demodulating a frequency shift keying (FSK) modulated signal, comprising:
an input node configured to receive an FSK modulated signal;
a phase-voltage converter (PVC) unit comprising:
a first PVC input node connected to the input node;
a second PVC input node; and
a PVC output node, the PVC unit configured to provide a control signal to the PVC output node based on a phase difference between the FSK modulated signal and a signal on the second PVC input node;
a voltage controlled delay line (VCDL) unit comprising:
a first VCDL input node connected to the input node;
a second VCDL input node connected to the PVC output node; and
a VCDL output node, the VCDL unit configured to adjust a phase of the FSK modulated signal based on the control signal to produce an adjusted signal, and to provide the adjusted signal to the VCDL output node,
wherein the second PVC input node is connected to the VCDL output node; and
an output node connected to the PVC output node, and configured to provide an FSK demodulated signal.

2. The circuit of claim 1, wherein the PVC unit comprises:
a phase frequency detector (PFD) unit configured to receive the FSK modulated signal and the adjusted signal, and to output an error signal indicating which of the FSK modulated signal and the adjusted signal is leading; and
a low pass filter arrangement configured to receive the error signal, and output the control signal based on the error signal.

3. The circuit of claim 2, wherein the low pass filter arrangement is configured to output the control signal by sourcing or sinking current based on the error signal.

4. The circuit of claim 3, wherein the low pass filter arrangement comprises:
a capacitor connected between the second VCDL input node and a reference potential node; and
a charge pump unit configured to receive the error signal, and to charge and discharge the capacitor based on the received error signal.

5. The circuit of claim 2, wherein the PFD unit is configured to compare the FSK modulated signal and the adjusted signal to generate a comparison result, and to output the error signal based on the comparison result, wherein:
responsive to the FSK modulated signal leading compared to the adjusted signal, the error signal, output by the PFD unit, has a first value, and
responsive to the FSK modulated signal lagging compared to the adjusted signal, the error signal, output by the PFD unit, has a second value.

6. The circuit of claim 1, wherein the VCDL unit comprises:
a fixed delay portion configured to adjust the FSK modulated signal according to a predetermined phase delay to generate an intermediate signal; and
a variable delay portion configured to adjust the intermediate signal based on the control signal.

7. The circuit of claim 1, further comprising an output conversion arrangement configured to receive the control signal from the PVC output node, and generate the FSK demodulated signal.

8. The circuit of claim 7, wherein the output conversion arrangement comprises a comparator configured to compare the control signal to a threshold voltage to generate a comparison result, wherein the FSK demodulated signal is generated based on the comparison result.

9. An isolation circuit, comprising:
an isolation barrier separating a first side from a second side;
a first signal modulator configured to generate an FSK modulated signal on the first side of the isolation barrier;
a communication means configured to communicate the FSK modulated signal across the isolation barrier; and
a first demodulation circuit configured to demodulate the FSK modulated signal, the first demodulation circuit provided on the second side of the isolation barrier,
wherein the first demodulation circuit comprises:
an input node configured to receive the FSK modulated signal;
a phase-voltage converter (PVC) unit comprising:
a first PVC input node connected to the input node;
a second PVC input node; and
a PVC output node, the PVC unit configured to provide a control signal to the PVC output node based on a phase difference between the FSK modulated signal and a signal on the second PVC input node;
a voltage controlled delay line (VCDL) unit comprising:
a first VCDL input node connected to the input node;
a second VCDL input node connected to the PVC output node; and
a VCDL output node, the VCDL unit configured to adjust a phase of the FSK modulated signal based on the control signal to produce an adjusted signal, and to provide the adjusted signal to the VCDL output node,
wherein the second PVC input node is connected to the VCDL output node; and
an output node connected to the PVC output node, and configured to provide an FSK demodulated signal.

10. The isolation circuit of claim 9, wherein the communication means comprises an oscillator configured to generate a carrier signal oscillating at a predetermined frequency.

11. The isolation circuit of claim 10, wherein the first signal modulator comprises a variable reactive load configured to alter a frequency of the carrier signal.

12. The isolation circuit of claim 9, further comprising an output comparator between the second side of the isolation barrier and the first demodulation circuit, the output comparator configured to transform the FSK modulated signal into a square wave having a same frequency as the FSK modulated signal.

13. The isolation circuit of claim 9, further comprising:
a second signal modulator configured to generate an amplitude shift keying (ASK) modulated signal on the second side of the isolation barrier, wherein the communication means is further configured to communicate the ASK modulated signal across the isolation barrier; and
a second demodulation circuit configured to demodulate the ASK modulated signal, the second demodulation circuit provided on the first side of the isolation barrier.

14. The isolation circuit of claim 11, further comprising:
a second signal modulator configured to generate an amplitude shift keying (ASK) modulated signal on the first side of the isolation barrier, wherein the communication means is further configured to communicate the ASK modulated signal across the isolation barrier; and
a second demodulation circuit configured to demodulate the ASK modulated signal, the second demodulation circuit provided on the second side of the isolation barrier.

15. The isolation circuit of claim 14, wherein the second signal modulator comprises a variable biasing current source or a variable resistor configured to alter an amplitude of the carrier signal.

16. The isolation circuit of claim 10, wherein the communication means comprises:
a transformer wherein the isolation barrier is formed between a first winding of the transformer and a second winding of the transformer; or
a capacitor, and wherein the isolation barrier is formed between a first plate of the capacitor and a second plate of the capacitor.

17. A method for demodulating a frequency shift keying (FSK) modulated signal, comprising:
receiving an FSK modulated signal;
providing a control signal based on a phase difference between the FSK modulated signal and a further signal;
adjusting a phase of the FSK modulated signal based on the control signal to produce an adjusted signal, wherein the further signal is the adjusted signal; and
outputting a demodulated FSK signal based on the control signal.

18. A method for communicating data across an isolation barrier separating a first side from a second side, comprising:
generating a frequency shift keying (FSK) modulated signal on the first side of the isolation barrier;
communicating the FSK modulated signal across the isolation barrier; and
demodulating the FSK modulated signal on the second side of the isolation barrier according to claim 17.

19. The method of claim 18, further comprising:
generating an amplitude shift keying (ASK) modulated signal on the second side of the isolation barrier;
communicating the ASK modulated signal across the isolation barrier; and
demodulating the ASK modulated signal on the first side of the isolation barrier.

20. The method of claim 18, further comprising:
generating an amplitude shift keying (ASK) modulated signal on the first side of the isolation barrier;
communicating the ASK modulated signal across the isolation barrier; and
demodulating the ASK modulated signal on the second side of the isolation barrier.
